(19) United States
(12) Patent Application Publication
(10) Pub. No.: US 2006/0261486 A1
(43) Pub. Date: Nov. 23, 2006

(54) Semiconductor device including interconnection structure in which lines having different widths are connected with each other

(75) Inventor: Masaki Yamada, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/495,786

(22) Filed: Jul. 31, 2006

Related U.S. Application Data
(62) Division of application No. 10/986,113, filed on Nov. 12, 2004.

(30) Foreign Application Priority Data
Mar. 11, 2004 (JP) 2004-069255

(51) Int. Cl. H01L 23/52

(52) U.S. Cl. 257/758

(57) ABSTRACT

A semiconductor device includes first and second lines. The first line is formed on a semiconductor substrate, and has a first width a. The second line is formed in the same interconnection layer as the first line on the semiconductor substrate, and has a second width b which is 0.2 μm or less. Ends of the first and second lines are connected with each other. The ratio of the first width a to the second width b (a/b) is less than 10.

The present application is a divisional of U.S. application Ser. No. 10/986,113, filed Nov. 12, 2004, the entire contents of which is incorporated herein by reference.

### CROSS-REFERENCE TO RELATED APPLICATIONS

This application is based upon and claims the benefit of priority from prior Japanese Patent Application No. 2004-069255, filed Mar. 11, 2004, the entire contents of which are incorporated herein by reference.

### BACKGROUND OF THE INVENTION

1. Field of the Invention

The present invention relates to a semiconductor device including an interconnection structure in which lines having different widths are connected together in the same interconnection layer on a semiconductor substrate.

2. Description of the Related Art

In important parts of computers or communication devices in recent years, a number of transistors and resistors, etc., are coupled to constitute an electric circuit. Also, a large number of computers or communication devices having such a structure have each adopted a large-scale integrated circuit (LSI) formed by integrating its members on one chip. Thus, the function of each device is greatly influenced by that of the LSI. The function of the LSI can be improved by increasing the integration density, i.e., reducing the size of an element.

The signal lines in the LSI have different widths, since the widths depend on the requisite amount of current and the complication of the circuit. That is, in order for the element to have a high performance, a wide line is provided to enable large current to flow therethrough, and a narrow line is provided as a line connected with a line in a lower-layer which is designed to have the minimum dimensions.

The sizes of elements are further reduced, and at the same time the sizes of the lines are decreased, and a larger number of layers are provided. As a result, the following problems arise:

In each of LSIs having such a structure, voids generate in a via connecting lines respectively provided in upper and lower layers. In order to solve this problem, it is proposed to limit the widths of the lines to be connected to the via (see, e.g., Jpn. Pat. Appln. KOKAI Publication No. 2002-124565).

Also, in LSIs, as is often the case, a wide line and a narrow line are connected with each other in the same interconnection layer. If lines having extremely different widths are connected together in the same interconnection layer, voids generate in the narrow line by stress migration, as a result of which the narrow line breaks.

### BRIEF SUMMARY OF THE INVENTION

A semiconductor device according to an aspect of the present invention includes first and second lines. The first line is formed on a semiconductor substrate, and has a first width a. The second line is formed in the same interconnection layer as the first line on the semiconductor substrate, and has a second width b which is 0.2 μm or less. Ends of the first and second lines are connected with each other. The ratio of the first width a to the second width b (a/b) is less than 10.

### BRIEF DESCRIPTION OF THE SEVERAL VIEWS OF THE DRAWING

FIG. 1 is a plan view of the structure of a semiconductor device according to a first embodiment of the present invention.

FIG. 2 is a perspective view of the structure of the semiconductor device according to the first embodiment of the present invention.

FIG. 3 is a cross-sectional view of the semiconductor device according to the first embodiment of the present invention.

FIG. 4 is a plan view of the structure of a semiconductor device according to a second embodiment of the present invention.

FIG. 5 is a perspective view of the structure of the semiconductor device according to the second embodiment of the present invention.

FIG. 6 is a cross-sectional view of the structure of the semiconductor device according to the second embodiment of the present invention.

FIG. 7 is a plan view of the structure of a semiconductor device according to a third embodiment of the present invention.

FIG. 8 is a graph indicating a relationship between the positions and the number of voids generated in samples having defects, according to the result of an experiment made with respect to the first embodiment.

FIG. 9 is a view showing an example of the layout of a circuit to which the first embodiment is applied.

### DETAILED DESCRIPTION OF THE INVENTION

The present invention will be explained with reference to the accompanying drawings. In the drawings and the following explanation, the same structural elements will be denoted by the same reference numerals, respectively.

### The First Embodiment

First, a semiconductor device including an interconnection structure according to the first embodiment of the present invention will be explained.

FIG. 1 is a plan view showing the structure of the semiconductor device including the interconnection structure according to the first embodiment of the present invention.

As shown in FIG. 1, a wide line 11 having a width a and a narrow line 12 having a width b are formed in the same interconnection layer on a semiconductor substrate, and are connected with each other. This embodiment is applied to a case where each of the width a of the wide line 11 and the width b of the narrow line 12 is 50 μm or less, and in particular a case where the width b of the narrow line 12 is 0.2 μm or less. The ratio of the width a of the wide line 11 to the width b of the narrow line 12 (i.e., a line width ratio a/b) is set to less than 10. Furthermore, the wide line 11 and the narrow line 12 are formed of, e.g., copper (Cu), silver (Ag) or aluminum (Al).

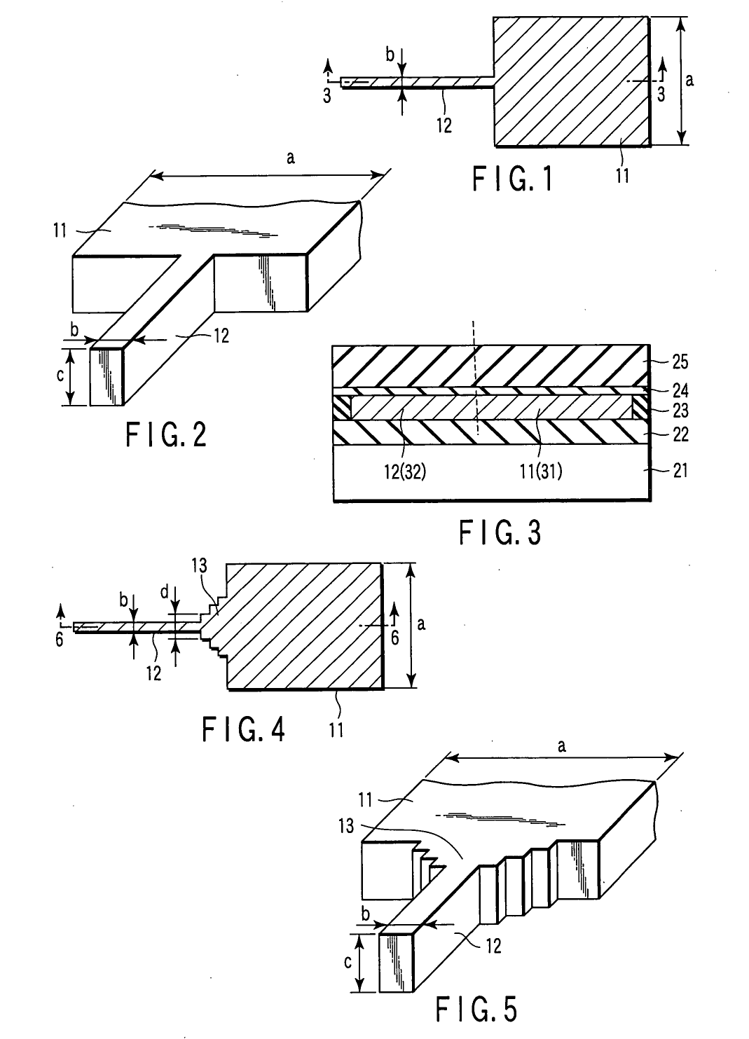

FIG. 2 is a perspective view showing the wide line 11 and the narrow line 12. As shown in FIG. 2, the wide line 11 and the narrow line 12 connected together in the same interconnection layer having the same height, i.e., a height c.

FIG. 3 shows a cross section taken along line 3-3 extending through the wide line 11 and the narrow line 12 as shown in FIG. 1. The wide line 11 and the narrow line 12 are manufactured in, e.g., a damascene method, which will be explained as follows:

As shown in FIG. 3, an insulating isolation layer 22 is formed on a semiconductor substrate 21. Then, an interlayer insulating film 23 is formed on the insulating isolation layer 22. In the interlayer insulating film 23, a line groove is formed in accordance with a line pattern. Thereafter, the line groove is filled with metal for line, thereby forming metal lines, i.e., a wide line 11 and a narrow line 12.

The following is an example of the above filling step:

Suppose the wide line 11 and the narrow line 12 are formed of copper. A tantalum film (now shown) serving as a barrier metal is deposited to have a thickness of approximately 10 nm in the line groove and on the interlayer insulating film 23 by a sputtering method. Also, copper is deposited to have a thickness of approximately 80 nm on the tantalum film by the sputtering method. Then, copper is formed to have a thickness of approximately 800 nm by a plating method.

Thereafter, the surface of the interlayer insulating film 23 is ground by a CMP method, thereby removing the surplus copper and tantalum from the surface of the interlayer insulating film 23. Then, an oxidation/diffusion preventing film 24 is formed on the wide line 11 and the narrow line 12 in order to prevent oxidation and diffusion of copper of which the wide line 11 and the narrow line 12 are formed. Further, a surface protection film 25 is formed on the oxidation/diffusion preventing film 24.

In the semiconductor device having the above interconnection structure, the ratio a/b of the width a of the wide line 11 to the width b of the narrow line 12 is set to less than 10. As a result, copper of the narrow line 12 which is taken in the wide line 11 is reduced, thereby restricting generation of voids in the narrow line 12, and preventing the narrow line 12 from breaking.

Next, after forming the wide line 11 and the narrow line 12 as shown in FIG. 3, an experiment was made to check whether a defect generated in the narrow line 12 or not. In this experiment, the wide line 11 and the narrow line 12 were made of copper. The experiment was made in the following manner:

Various samples were prepared as a first group of samples. They were different from each other with respect to the ratio (a/b) of the width a of the wide line 11 to the width b of the narrow line 12. In each of the samples, the width b of the narrow line 12 was approximately 90 nm, and the height c of each of the wide line 11 and the narrow line 12 was approximately 160 nm.

Also, various samples were prepared as a second group of samples differing from each other with respect to the aspect ratio (c/b) of the narrow line 12. In each of the second group of samples, the width b of the narrow line 12 was 0.2 μm or less, and the heights c of the wide line 11 and the narrow line 12 were approximately 160 nm.

After each of the first and second groups of samples was left at 225° C. for 1600 hours, it was checked whether a defect generated in the narrow line 12 connected with the wide line 11. The result of this experiment is shown in following tables 1 and 2:

TABLE 1

| | a/b | | | | | | |
|---|---|---|---|---|---|---|---|
| | 10.5 | 10 | 8.3 | 7.1 | 5 | 2 | 1 |
| Percentage | 15.5 | 10.0 | 0 | 0 | 0 | 0 | 0 |
| defective(%) | | | | | | | |

TABLE 2

| | c/b | | | | |
|---|---|---|---|---|---|
| | 1.68 | 1.6 | 1.33 | 1.14 | 0.8 |
| Percentage | 7.5 | 10.0 | 2.5 | 0 | 0 |
| defective(%) | | | | | |

Table 1 indicates the percentage defectives of first group of samples differing from each other with respect to the ratio (a/b) of the width a of the wide line 11 to the width b of the narrow line 12. Table 2 indicates the percentage defectives of second group of samples which differed from each other with respect to the ratio (c/b) of the height c of the narrow line 12 to the width b of the narrow line 12, and which were each set such that the ratio (a/b) of the width a of the wide line 11 to the width b of the narrow line 12 was 10 or more.

When the samples were observed after the experiment, it was confirmed that voids generated in defective narrow lines 12. As shown in table 1, it was confirmed that the line width ratio a/b of each of the samples having defective narrow lines 12 was 10 or more, i.e., the narrow lines 12 of the samples whose line width ratios a/b were less than 10 were not defective. Furthermore, of the samples whose line width ratios a/b were 10 or more, samples having narrow lines 12 whose ratios c/b (ratios of the heights c to the widths b of the narrow lines 12) were 1.1 or less were not defective.

As explained above, in the first embodiment, in a structure in which the wide line and the narrow line are connected in the same interconnection layer, the ratio of the width of the wide line to that of the narrow line and the aspect ratio of the narrow line are specified, thereby restricting generation of voids in the narrow line, and preventing the narrow line from breaking.

Also, in the majority of samples having narrow lines each having a width of more than 0.2 μm, voids did not generate in the narrow lines, nor did the narrow lines break. Therefore, the first embodiment of the present invention is applied to a case where the width of the narrow line is 0.2 μm or less. Furthermore, the first embodiment can also be applied to both a semiconductor device having a multi-layer line or a semiconductor device having a single-layer line. This is true of the second and third embodiments which will be explained as set out below.

### The Second Embodiment

A semiconductor device including an interconnection structure according to the second embodiment of the present invention will be explained. With respect to the second embodiment, the same structural elements as in the first embodiment will be denoted by the same reference numerals, respectively.

FIG. 4 is a plan view of the structure of the semiconductor device including the interconnection structure according to the second embodiment.

A wide line 11 having a width a and a narrow line having a width b are formed in the same interconnection layer on a semiconductor substrate. The ratio (a/b) of the width a of the wide line 11 to the width b of the narrow line 12 is set to 10 or more, and the aspect ratio (c/b) of the narrow line 12 is set to 1.2 or more. In this case, as shown in FIG. 4, an intermediate line 13 is provided between the wide line 11 and the narrow line 12, and the wide line 11 and the narrow line 12 are connected together, with the intermediate line 13 interposed therebetween. The intermediate line 13 has a width d which is smaller than the width a of the wide line 11, and is greater than the width b of the narrow line 12 (a>d>b). Therefore, the ratio of the width of the intermediate line 13 to that of the narrow line 12 is set so as not to exceed 10. Also, the ratio of the width of the wide line 11 to that of the intermediate line 13 is set so as not to exceed 10. The intermediate line 13 may be formed in a stepwise manner such that its width increases by degrees toward the wide line 11 as shown in FIG. 4.

Also, the second embodiment, as well as the first embodiment, is applied to a case where each of the width a of the wide line 11, the width b of the narrow line 12 and the width of the intermediate line 13 is 50 μm or less, and in particular a case where the width b of the narrow line 12 is 0.2 μm or less. Furthermore, the wide line 11, the narrow line 12 and the intermediate line 13 are formed of, e.g., copper (Cu), silver (Ag) or aluminum (Al).

FIG. 5 is a perspective view showing the wide line 11, the narrow line 12 and the intermediate line 13.

The wide line 11, the narrow line 12 and the intermediate line 13 are formed in the same interconnection layer to have the same height, i.e., a height c.

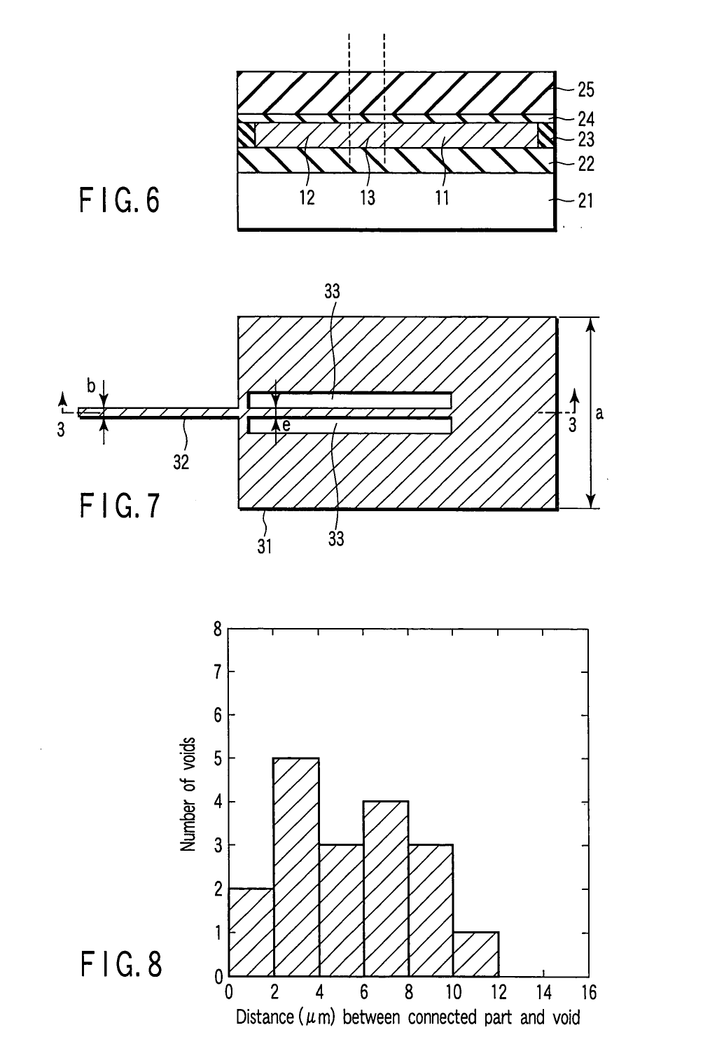

FIG. 6 shows a cross section taken along line 6-6 extending trough the wide line 11, the narrow line 12 and the intermediate line 13, which is shown in FIG. 4. The wide line 11, the narrow line 12 and the intermediate line 13 are manufactured in, e.g., a damascene method, which will be explained as follows:

As shown in FIG. 6, an insulating isolation layer 22 is formed on the semiconductor substrate 21, and then an interlayer insulating film 23 is formed on the insulating isolation layer 22. A line groove is formed in the interlayer insulating film 23 in accordance with a line pattern. Then, the line groove is filled with metal for line, thereby forming metal lines, i.e., a wide line 11, a narrow line 12 and an intermediate line 13.

The following is an example of the above filing method:

Suppose the wide line 11, the narrow line 12 and the intermediate line 13 are formed of copper. A tantalum film (now shown) serving as a barrier metal is deposited to have a thickness of approximately 10 nm in the line groove and on the interlayer insulating film 23 by a sputtering method. Also, copper is deposited to have a thickness of approximately 80 nm on the tantalum film by the sputtering method. Furthermore, copper is deposited to have a thickness of approximately 800 nm by a plating method.

Thereafter, the surface of the interlayer insulating film 23 is ground by a CMP method, thereby removing the surplus copper and tantalum from the surface of the interlayer insulating film 23. Then, an oxidation/diffusion preventing film 24 is formed on the wide line 11, the narrow line 12 and the intermediate line 13 in order to prevent oxidation and diffusion of the copper constituting the wide line 11, the narrow line 12 and the intermediate line 13. Further, a surface protection film 25 is formed on the oxidation/diffusion preventing film 24.

In the semiconductor device having the above interconnection structure, the wide line 11 and the narrow line 12 are connected together, with the intermediate line 13 interposed therebetween, and the ratio a/b of the width a of the wide line 11 to the width b of the narrow line 12 is set to less than 10. As a result, copper of the narrow line 12 which is taken in the wide line 11 is reduced, thereby restricting generation of voids in the narrow line 12, and preventing the narrow line 12 from breaking.

Next, after forming the wide line 11, the narrow line 12 and the intermediate line 13 as shown in FIGS. 4-6, an experiment was made to check whether a defect generated in the narrow line 12 or not. In this experiment, the width b of the narrow line 12 was 0.2 μm or less, and the wide line 11, the narrow line 12 and the intermediate line 13 were made of copper. The experiment was made in the following manner:

Various samples were prepared as a third group of samples. They were different from each other with respect to the ratio (a/b) of the width a of the wide line 11 to the width b of the narrow line 12. In each of the samples, the width b of the narrow line 12 was approximately 90 nm, and the height c of each of the wide line 11 and the narrow line 12 was approximately 160 nm. The intermediate line 13 was formed to have three steps on one side such that the width increased by 40 nm in one step on one side in a direction away from the narrow line 12. For example, when the width of the narrow line 12 was 90 nm, the width of the intermediate line 13 varied from 170 nm to 250 nm, and then to 330 nm in a direction away from the narrow line 12 toward the wide line 11.

Furthermore, various samples were prepared as a fourth group of samples. They were different from each other with respect to the aspect ration (c/b) of the narrow line 12. The width b of the narrow line 12 was 0.2 μm or less, and the height c of each of the wide line 11 and the narrow line 12 was approximately 160 nm. In the same manner as stated above, the intermediate line 13 was formed to have three steps on one side such that the width increased by 40 nm in one step on one side from the narrow line 12. In addition, the ratio (a/b) of the width a of the wide line 11 and the width b of the narrow line 12 was set to 10 or more.

After each of the third and fourth groups of samples was left at 225° C. for 1600 hours, it was checked whether a defect generated in the narrow line 12 connected with the wide line 11. The result of this experiment is shown in the following tables 3 and 4:

TABLE 3

| | a/b | | | | |
|---|---|---|---|---|---|
| | 10.5 | 10 | 8.3 | 7.1 | 5 |
| Percentage | 0 | 0 | 0 | 0 | 0 |
| defective(%) | | | | | |

TABLE 4

C/b

| | 1.68 | 1.6 | 1.33 | 1.14 |
|---|---|---|---|---|
| Percentage | 0 | 0 | 0 | 0 |
| defective(%) | | | | |

Table 3 indicates the Percentage defectives of third group of samples differing from each other with respect to the ratio (a/b) of the width a of the wide line 11 to the width b of the narrow line 12. Table 2 indicates the Percentage defectives of fourth group of samples which differed from each other with respect to the ratio (c/b) of the height c of the narrow line 12 to the width b of the narrow line 12, and which were each set such that the ratio (a/b) of the width a of the wide line 11 to the width b of the narrow line 12 was 10 or more.

When the samples were observed after the experiment, it was confirmed that none of their narrow line 12 had a defect as shown in table 3. As stated above, in the first embodiment, defects generated in the samples whose ratios a/b were 10 or more. On the other hand, with respect to the second embodiment, it was confirmed that even the samples whose ratios a/b were 10 or more did not have a defect. Furthermore, as shown in table 4, even the samples whose ratios a/b were 10 or more and whose ratios c/b were 1.2 or more did not have a defect.

As explained above, in the second embodiment, the wide line and the narrow line are connected to each other, with the intermediate line interposed therebetween, and the width of the intermediate line is smaller than that of the wide line, and greater than that of the narrow line. This structure can restrict generation of voids in the narrow line, and prevent the narrow line from breaking.

### The Third Embodiment

A semiconductor device including an interconnection structure according to the third embodiment of the present invention will be explained. With respect to the third embodiment, the same structural elements as in the first embodiment will be denoted by the same reference numerals, respectively.

FIG. 7 is a plan view of the structure of the semiconductor device including the interconnection structure according to the third embodiment.

In the third embodiment, a wide line 31 having a width a and a narrow line having a width b are formed in the same interconnection layer, and the ratio a/b of the width a of the wide line 31 to the width b of the narrow line 32 is 10 or more. The third embodiment, as well as the first embodiment, is applied to a case where to a case where each of the width a of the wide line 31 and the width b of the narrow line 32 is 50 μm or less, and in particular a case where the width b of the narrow line 32 is 0.2 μm or less.

In the third embodiment, as shown in FIG. 7, slits 33 are formed in part of the wide line 31 which is close to the narrow line 32. The slits 33 are opening regions in which line material is not present. Also, the slits 33 are rectangularly shaped such that their longitudinal direction coincides with the longitudinal direction of the narrow line 32. It is preferable that the number of slits 33 formed in the wide line 31 be two, the two slits 33 be arranged in such a manner as to sandwich part of the wide line 31 which extends from the narrow line 32, and the ratio of the distance e between the two slits 33 width to the width b of the narrow line 32 (i.e., ratio e/b) be set to less than 10. In the structure shown in FIG. 7, the two slits 33 are arranged opposite to each other with respect to the above part of the wide line 31 which extends from the narrow line 32. That is, where the wide line 31 is divided into two sides with respect to the above part of the wide line 31, the number of slits 33 provided on one side of the wide line 31 is one. However, two or more slits 33 may be provided on one side.

FIG. 3 shows a cross section of each of the wide line 31 and narrow line 32, which is taken along line 3-3 in FIG. 7. The narrow line 32 and the wide line 31 including the slits 33 are manufactured in, e.g., a damascene method, which will be explained as follows:

As shown in FIG. 3, an insulating isolation layer 22 is formed on a semiconductor substrate 21, and then an interlayer insulating film 23 is formed on the insulating isolation layer 22. A line groove is formed in the interlayer insulating film 23 in accordance with a line pattern. At this time, insulating film (not shown) for formation of the slits 33 remains in a projected state in a region of the line groove in which the wide line 31 is to be formed. Thereafter, the line groove is filled with metal for line, so that the wide line 31 and the narrow line 32 are formed such that slits 33 are formed in the wide line 31.

The above filling step is carried out in the following manner.

Suppose the wide line 31 and the narrow line 32 are formed of copper. A tantalum film (not shown) serving as a barrier metal is deposited to have a thickness of approximately 10 nm in the line groove and on the interlayer insulating film 23 by a sputtering method. Also, copper is deposited to have a thickness of approximately 80 nm on the tantalum film by the sputtering method. Then, copper is deposited to have a thickness of approximately 800 nm by a plating method.

Thereafter, the surface of the interlayer insulating film 23 is ground by a CMP method, thereby removing the surplus copper and tantalum from the surface of the interlayer insulating film 23. Then, an oxidation/diffusion preventing film 24 is formed on the wide line 31 and the narrow line 32 in order to prevent oxidation and diffusion of copper of which the wide line 31 and the narrow line 32 are formed. Further, a surface protection film 25 is formed on the oxidation/diffusion preventing film 24.

In the semiconductor device having the above interconnection structure, slits 33 are formed in the wide line 31. As a result, copper of the narrow line 32 which is taken in the wide line 31 is reduced, thereby restricting generation of voids in the narrow line 32, and preventing the narrow line 32 from breaking.

FIG. 8 shows a relationship between the positions and the number of voids generated in the samples in which defects generated in the experiment referred to with respect to the first embodiment. In the figure, the positions of the voids are indicated by the distances between the voids and connected part between the wide line 11 and the narrow line 12. The voids generated in the narrow line 12 only. To be more specific, they generated in an area of the narrow line 12 which is located from the above connected part to a position apart therefrom by 12 μm in a direction away from the wide line 11. That is, no void generated in the other area of the narrow line 12, i.e., an area separated from the connected part by more than 12 μm in the direction away from the wide line 11.

In the third embodiment, since the slits 33 are formed in the wide line in the above manner, an area similar to the narrow line is provided in the wide line as shown in FIG. 7. Then, when the length of each of the slits 33 is 15 μm or more, it can be considered that voids generate only in the wide line; they do not generate in the narrow line. In such a manner, even if voids generate in the wide line, the wide line does not break. This is because the wide line is formed as if it were divided into three parts by the slits 33 as shown in FIG. 7.

As explained above, in the third embodiment, in the structure wherein the wide line and the narrow line are connected in the same interconnection layer, slits are formed in the wide line in such a manner as to sandwich an area of the wide line which continuously extends from the narrow line, thereby restricting generation of voids in the narrow line, and preventing the narrow line from breaking.

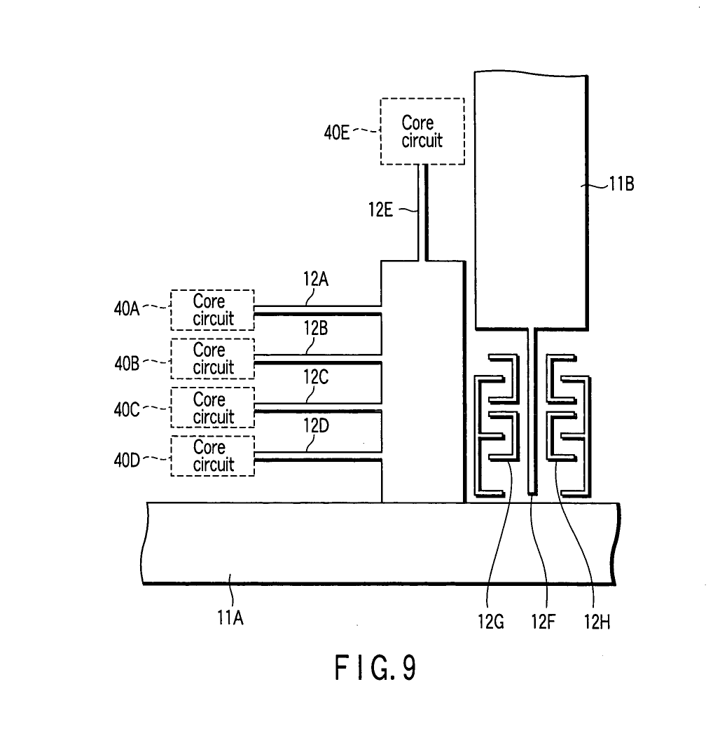

FIG. 9 shows an example of the layout of a circuit which adopts the first embodiment. To be more specific, FIG. 9 partially shows the layout of an interconnection layer.

As shown in FIG. 9, wide lines 11A and 11B are provided as signal lines in an interconnection layer. A plurality of narrow lines 12A, 12B, 12C, 12D and 12E extend from the wide line 11A, and are connected to core circuits 40A, 40B, 40C and 40D, respectively. Each of the core circuits 40A, 40B, 40C and 40D is a circuit for achieving a predetermined electric function, and also has a pattern formed in a multi-interconnection layer including the interconnection layer shown in FIG. 9.

Furthermore, a narrow line 12F extends from the wide line 11B, and is located between patterns 12G and 12H. The pattern 12G, the narrow line 12F and the pattern 12H are arranged at small intervals according to design rules.

As explained above, the narrow lines 12A-12E are used as lines connecting the wide line 11A and the cores 40A-40E, respectively, or used as five of the lines arranged at small intervals. The above structure is explained by referring to the case where the wide and narrow lines are signal lines. However, it may be applied to the case where the wide and narrow lines are lines for a power supply. Also, the above structure is explained by referring to the case where the first embodiment is applied to the structure. However, the second and third embodiments can be applied to the structure.

According to each of the first to third embodiments, a semiconductor device can be provided with an interconnection structure in which a narrow line and a wide line are formed in the same interconnection layer, while restricting generation of voids in the narrow line, and preventing the narrow line from breaking.

Moreover, the first to third embodiments can be applied in combination. Needless to say, these embodiments can be also applied alone. In addition, the embodiments include inventions of various stages, which can be extracted by arbitrarily selectively combining the structural elements in the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a first line formed on a semiconductor substrate, and having a first width a; and
a second line formed in the same interconnection layer as the first line on the semiconductor substrate, and having a second width b which is 0.2 μm or less;
wherein ends of the first and second lines are connected with each other, a ratio of the first width a to the second width b (a/b) is 10 or more, and a slit is formed in part of the first line which is close to connected part between the first and second lines.

2. The semiconductor device according to claim 1, wherein a plurality of slits including the slit are arranged to sandwich part of the first line which extends from the second line.

3. The semiconductor device according to claim 1, wherein the slit extends such that a longitudinal direction thereof is coincident with a longitudinal direction of each of the first and second lines.

4. The semiconductor device according to claim 2, wherein the slit has a length of 12 μm or more in a longitudinal direction of the slit.
